(19) United States
(12) Patent Application Publication
(10) Pub. No.: US 2007/0285688 A1
(43) Pub. Date: Dec. 13, 2007

(54) Color gamut contour creating system

(75) Inventors: Ryosuke Higashikata, Kanagawa (JP); Tomoko Taguchi, Kanagawa (JP); Kiyoshi Une, Saitama (JP)

Correspondence Address: OLIFF & BERRIDGE, PLC, P.O. BOX 19928, ALEXANDRIA, VA, 22320, US

(73) Assignee: FUJI XEROX CO., LTD., TOKYO (JP)

(21) Appl. No.: 11/638,355

(22) Filed: Dec. 14, 2006

(30) Foreign Application Priority Data
Jun. 13, 2006 (JP) 2006-163752

(51) Int. Cl. G03F 3/08

(52) U.S. Cl. 358/1.9; 358/518

(57) ABSTRACT

The present invention provides a color gamut contour creating device that includes a color gamut contour creating component and a color gamut contour smoothing component. The color gamut contour creating component generates color gamut contour data representing a color gamut contour of a color reproducing range in a preset color space of an output side device. The color gamut contour smoothing component generates smoothed color gamut contour data of the color gamut contour where the color gamut contour is smoothed based on the color gamut contour data.

### BACKGROUND

1. Technical Field

The present invention relates to a color gamut contour creating device, a method for creating a color gamut contour, and a storage media for storing a color gamut contour program. More specifically, the present invention relates to a color gamut contour creating device, a method for creating a color gamut contour, and a storage media for storing a color gamut contour program that create a color gamut contour used when performing color conversion processing on a color image signal in a case where the color reproducible regions of a color image signal of an input side device and output side device differ.

2. Related Art

In the calculation of color conversion parameters from a simulation object device to an outputting object device, and in calculation of a color lookup table (CLUT) of a BtoAx tag in an ICC profile, calculation of color conversion parameters is necessary. This calculation is performed from device color signals of the simulation object device (e.g., CMYK color signals) and device-independent color signals that do not depend on the device to device color signals.

Then when calculating the color conversion parameters, it is necessary to perform gamut mapping that maps the device-independent color signal within the color reproduction range of the output object device so that colors outside of the color reproduction range of the output object device can be reproduced. Here, an example of the object of the color conversion parameter includes a group of device color signals of an output object device, where a color space has been divided into a grid pattern that forms a multidimensional table. When conducting this gamut mapping, it is usually necessary to calculate the contours of the color gamut (color reproducing range) of the output object device, or else to calculate it in advance. For this reason, various conventional methods are known.

### SUMMARY OF THE INVENTION

According to an aspect of the present invention, there is provided a color gamut contour creating device that includes a color gamut contour creating component and a color gamut contour smoothing component. The color gamut contour creating component generates color gamut contour data representing a color gamut contour of a color reproducing range in a preset color space of an output side device. The color gamut contour smoothing component generates smoothed color gamut contour data of the color gamut contour where the color gamut contour is smoothed based on the color gamut contour data.

### BRIEF DESCRIPTION OF THE DRAWINGS

Exemplary embodiments of the present invention will be described in detail based on the following figures, wherein:

FIG. 1 is a block diagram showing an example of a general configuration of a color conversion device according to the present invention;

FIG. 2 is a block diagram showing an example of a general configuration of a color space signal converter in the color conversion device;

FIG. 3 is a flowchart of processing executed at the color space signal converter in a first exemplary embodiment of the present invention;

FIG. 4 is a conceptual diagram showing an example of color reproducing range;

FIG. 5 is a conceptual diagram for explaining 2-D smoothing processing;

FIG. 6 is a conceptual diagram for explaining filter coefficients of a filter;

FIG. 7 is a flowchart of processing executed at the color space signal converter in a second exemplary embodiment of the present invention;

FIG. 8 is a projected diagram showing a portion of the color reproducing range of an output side device in a case where the amount of color is limited; and

FIG. 9 is a flowchart of smoothing processing.

### DETAILED DESCRIPTION

### First Exemplary Embodiment

Hereafter, a first exemplary embodiment of the present invention will be explained while referring to the drawings.

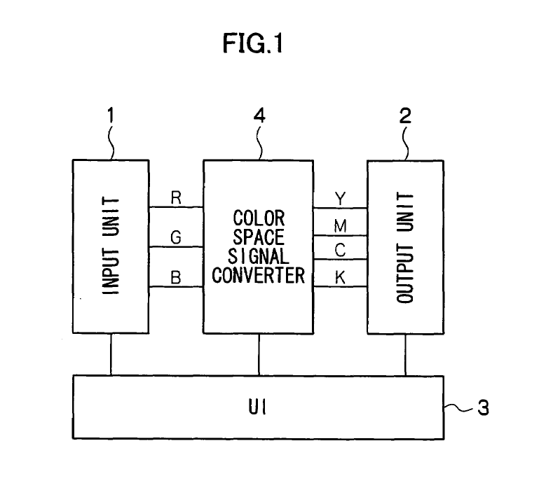

First, the general configuration of the color conversion device will be explained. FIG. 1 is a block diagram showing an example of a general configuration of the color conversion device according to the present invention. The color conversion device explained here is installed and used in an image outputting device such as a digital photocopier or a printer, or in a server device connected to such an image outputting device, or alternately, in a computer (i.e., driver device) that provides operational commands to the image outputting device. As shown in the illustrated example, the color conversion device is provided with an input unit 1, an output unit 2, a user interface 3 (hereafter, “UI”), and a color space signal converter.

The input unit 1 is for obtaining an inputted image signal from a device at the inputting side. Examples of the inputted image signal include, for example, a color image signal in a RGB color space for displaying onto a CRT and the like. In this exemplary embodiment, explanations will be made regarding a case where the inputted image signal is a color image signal in a RGB color space.

The output unit 2 is for outputting an outputted image signal to a device at the outputting side. Examples of the outputted image signal include, for example, a color image signal in a YMC color space or a YMCK color space for printing with a printer and the like. In this exemplary embodiment, explanations will be made regarding a case where the outputted image signal is a color image signal in a YMCK color space.

The UI 3, which is for performing various settings for the color space signal converter, is operated by the user.

The color space signal converter is for converting the inputted image signal that the input unit 1 obtained into the outputted image signal outputted at the output unit 2. The inputted image signal is converted into the outputted image signal due to the performance of conversion processing on the inputted image signal with the color space signal converter. Further, color conversion is performed with the color space signal converter after smoothing the color reproducing range contours of the device of the output side so that gradation jumps and the like are not generated after color conversion.

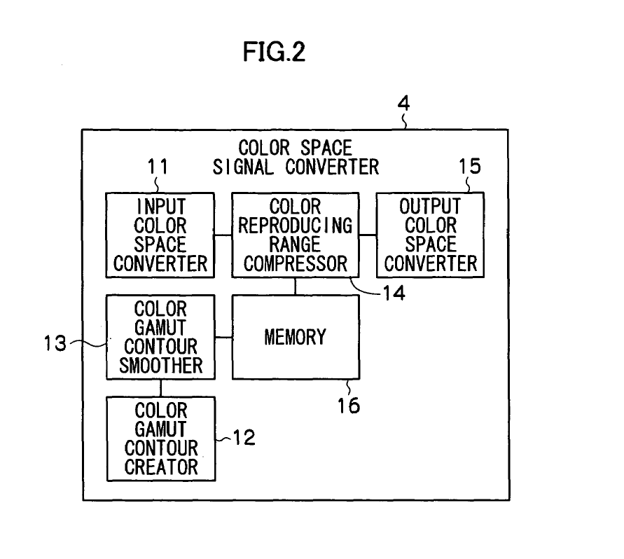

Here, further detailed explanations on the color space signal converter will be given. FIG. 2 is a block diagram showing an example of a general configuration of a color space signal converter. As shown in the illustrated examples, the color space signal converter is provided with an input color space converter 11, a color gamut contour creator 12, a color gamut contour smoother 13, a color reproducing range compressor 14, an output color space converter 15, and a memory 16.

When the color space of the inputted image signal differs from the color space used at a later step, the input color space converter 11 performs color space conversion processing on the color space used at a later step. When, for example, the input image signal is a signal of a RGB color space, conversion to a color space with the color reproducing range compressor 14 not dependent on the device (e.g., CIE-L*, a*, b* color space) is performed with the input color space converter 11. With this exemplary embodiment, explanations will be made regarding a case where, for the color space not dependant on the device, a CIE-L*a*b* color space was used. Nonetheless, the present invention is not thus limited, and other color spaces that do not depend on the device such as Jch and the like can also be used.

Note that when the inputted image signal is the signal of a color space that does not depend on the device, it is not necessary to provide this input color space converter 11 since the processing in the input color space converter 11 becomes unnecessary.

The color gamut contour creator 12 creates color gamut contour data that shows the color gamut contour of the color reproducing range of the device at the output side.

The color gamut contour smoother 13 smoothens the color gamut contour of the output side device based on the color gamut contour data of the output side device created with the color gamut contour creator 12, and stores the smoothened color gamut contour data of the smoothened color gamut contour in the memory 16.

The color reproducing range compressor 14 maps the inputted image signal outputted from the input color space converter 11 to a signal in the color reproducing range of the output side device smoothened with the color gamut contour smoother 13, and converts it to an outputted image signal.

When the color space of the outputted image signal differs from the color space used at the image outputting device of the output side that receives this outputted image signal, the output color space converter 15 performs color space conversion processing so that the color space becomes the one used in the image outputting device. For example, in a case where the image outputting device is a printer and the like, these image outputting devices almost always handle image signals of a YMC color space or a YMCK color space. In this type of situation, the output color space converter 15 performs color space conversion processing to a color space that does not depend on the device, e.g., from CIE-L*a*b* color space to YMC color space or YMCK color space. Of course, the color space not depending on the device can be outputted as is, and in this case, the image signal processor can be configured without the output color space converter 15 since the processing in the output color space converter 15 becomes unnecessary.

Color reproducing range data that shows the color reproducing range of the device at the inputting side and color reproducing range data that shows the color reproducing range of the device at the outputting side is stored in the memory 16 with the program of a processing routine that will be described later.

Each of these components 11-16 are provided in, for example, an image outputting device, a server device or a driver device. Each of these components can be thought of as being implemented due to the execution of a preset program with a computer that consists of a combination of parts such as a central processing unit (CPU), a read-only memory (ROM), and a random-access memory (RAM).

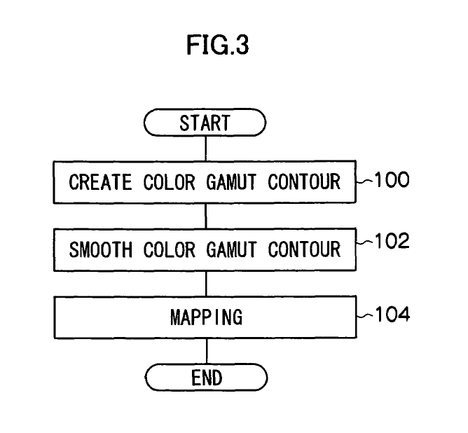

Next, the processing routine executed with the color space signal converter will be explained while referring to the flowchart shown in FIG. 3. Note that the processing shown in FIG. 3 is executed when, e.g., conversion of color is instructed by a user operating the UI 3.

First, at Step 100, the color gamut contour creator 12 creates the color gamut contour of the color reproducing range of the device at the outputting side and generates color gamut contour data showing this color gamut contour. The created color gamut contour can be sought in a color space that is not dependant on the device, e.g., a CIE-L*a*b* color space. Note that in the following explanations, the internal processing is performed in a CIE-L*a*b* color space.

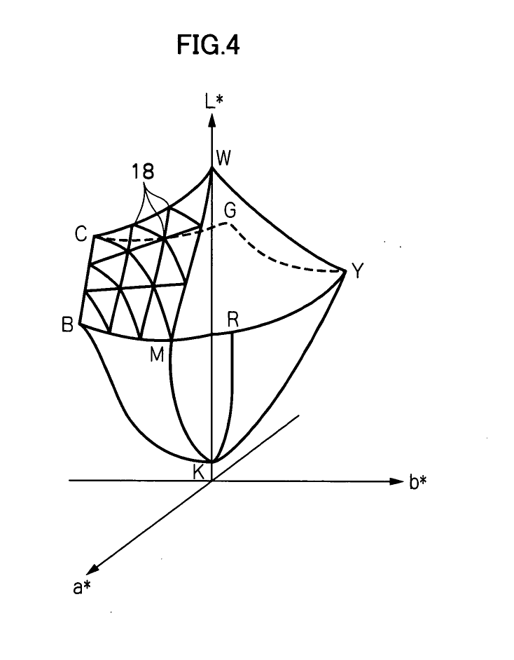

FIG. 4 is a conceptual diagram showing an example of color reproducing range. Usually, the color reproducing range is not uniform and it tends to have a complicated 3-D form such as in the illustrated example. The inner side of the solid body shown in the drawing is a region where color can be reproduced and the outer side thereof is a region where color cannot be reproduced. Accordingly, when seeking the color reproducing range, information (color gamut contour data) on the surface (contour surface) showing the boundary between the region where color reproduction is possible and the region where color reproduction is not possible is sought. As discussed above, the form of this contour surface is not uniform so this can be expressed by, e.g., breaking it into polygons such as triangles. In the illustrated example, only a portion of the contour surface was divided into triangles and displayed, however, in actual practice, this kind of division is performed for the entire surface of the contour surface. The color gamut contour data makes the apex of each polygon into a contour composition point, and can be made into information relating to the position inside the CIE-L*a*b* color space of that contour composition point. For example, when the contour surface is divided into triangular forms, the color gamut contour data can take the form of a contour surface lookup table showing the corresponding relations between the brightness, color saturation, and hue angle of each of the triangles.

The contour data showing the contours of the sought color reproducing range of the device at the output side is output to the color gamut contour smoother 13.

At Step 102, smoothing processing that smoothes the color gamut contour made at Step 100 is performed based on the color gamut contour data, and smoothened color gamut contour data is generated.

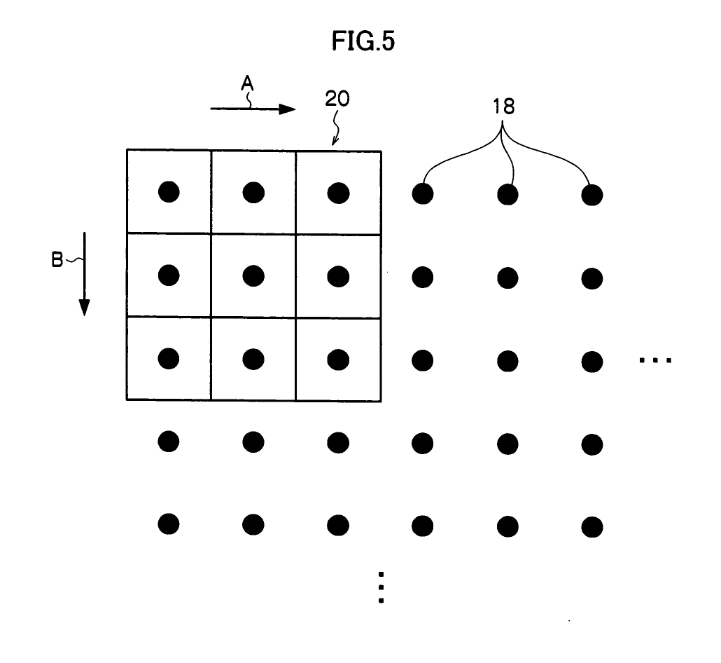

Hereafter, an outline of the smoothing processing will be explained. In a case where, for example, the color reproducing range of the output side device is like that shown in FIG. 4, a filter 20 is arranged so that the surfaces forming the color reproducing range shown in FIG. 4 are regularly arranged in, e.g., a virtual pattern as shown in FIG. 5, with each contour composition point 18 (the apex of each triangular polygon shown in FIG. 4) on the surfaces made by joining W (white), C (cyan), B (black), and M (magenta). The filter 20 is arranged so that the contour composition points of the objects to be smoothed correspond to the matrix of the center of the filter 20 forming a 3×3 matrix for smoothing. Note that for the filter 20, a known filter can be used, e.g., the local weighted average filter recited in the aforementioned Image Analysis Handbook, but is not limited thereto.

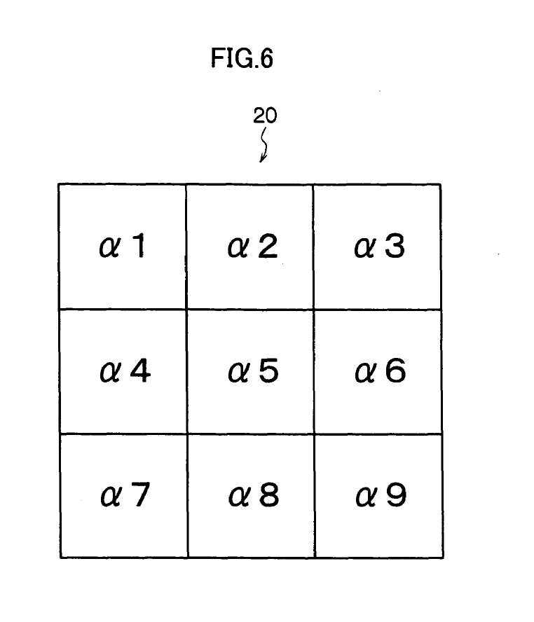

The filter 20 has a preset filter coefficient in each 3×3 matrix of α1-α9, as shown in FIG. 6. The filter uses this filter coefficient to convert each of the color saturation values of the contour composition points corresponding to each matrix (each filter coefficient). Next, the filter 20 is moved one portion of contour composition points in the direction of the A arrow in FIG. 5. That is, the contour composition points to be smoothed are shifted one portion of contour composition points. Then, just as described above, the color saturation value of the contour composition points corresponding to each matrix is converted. When this is performed for one row of contour composition points, one portion of contour composition points are shifted in the direction of the B arrow in FIG. 5 and, as above, the color saturation value of the contour composition points corresponding to each matrix is converted. By performing this process within the entire surface, the form of the surface can be smoothed. Then the same smoothing processing is performed for other surfaces. With this, all of the contours of the color reproducing range of the device at the outputting side can be smoothened.

Note that in FIG. 4, the white (W) portion of the color reproducing range becomes an inferior form first and it is not preferable to smooth it. For this reason, when the apex of the surface to be smoothed includes white (W), it is preferable to do smoothing processing for contour composition points where that apex has been removed. Also, not just with white but in any case there is an apex for which it is better to not perform smoothing processing, the smoothing processing should be performed so that the apex is removed. Also, the process can be performed so that the coefficient of the filter 20 is matched to the state of the protrusions and depressions on the surface of the color gamut contour and changed. For example, the dispersion of the color saturation differences between the color saturation of the contour composition points of the object to be smoothed and the color saturation of the peripheral contour composition points can be sought, so that the pattern of the filter coefficient of the filter 20 is selected in accordance with the sought dispersion. Also the above-described smoothing processing can be configured so that the processing is executed repeatedly and not just one time. For example, the smoothing processing can also be performed so as to be repeated until the dispersion of the color saturation differences between the color saturation of the contour composition points of the object to be smoothed and the color saturation of the peripheral contour composition points reach at or below a threshold.

Then, at Step 104, the inputted image signal is converted to an outputted image signal of within the smoothed color reproducing range of the output side device with a preset color converting method.

In this manner, with this exemplary embodiment, the smoothness of the contour surface of the color reproducing range of the outputting side device can be made to improve due to the smoothing processing. Even if a kind of mapping that depends on the state of the contour surface of the color reproducing range is performed, it becomes possible to suppress deterioration of the gradation qualities. Further, for just smoothing the contour surface of the color reproducing range, only a relatively small amount of correction is performed, so the reproductive qualities of the color mapped on the contour of the color reproducing range of the outputting side device can be almost entirely maintained. Further, it becomes possible to prevent negative influences on the color reproducing qualities within the color reproducing range.

### Second Exemplary Embodiment

Next, the second exemplary embodiment of the present invention will be explained. Note that portions that are the same as those in the first exemplary embodiment are provided with the same code numbers, and detailed explanations thereon will be omitted. In this exemplary embodiment, explanations will be given regarding a case where a total limit on color material is imposed on the output side device.

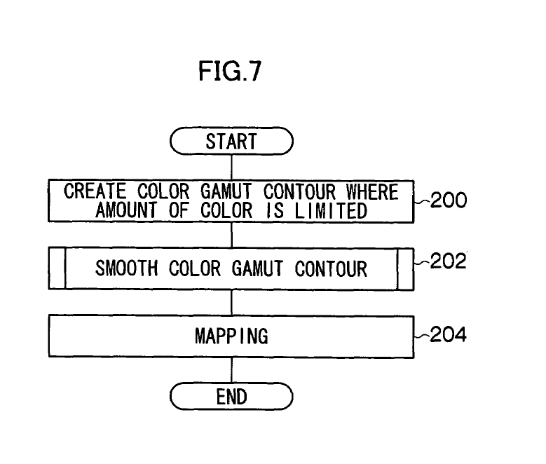

The device configuration is the same as in FIG. 2 so the processing routine executed by the color space signal converter 4 will be explained while referring to the flowchart shown in FIG. 7.

As shown in FIG. 7, at Step 200, the color gamut contour creator 12 creates the color gamut contour of the color reproducing range of the output side device and generates color gamut contour data showing this color gamut contour, however, in this exemplary embodiment, a color gamut contour is created where a total limit on color material is imposed on the output side device. If the colors handled by the output side device are the four colors of YMCK, the total amount of color in a case where a limit is not imposed on the total amount of color is 400%. However, when a limit is imposed so that the amount of color becomes 250%, the color gamut contour is made so that the amount of color becomes 250%. That is, the color gamut is reduced only by the portion of the limit placed on the amount of color.

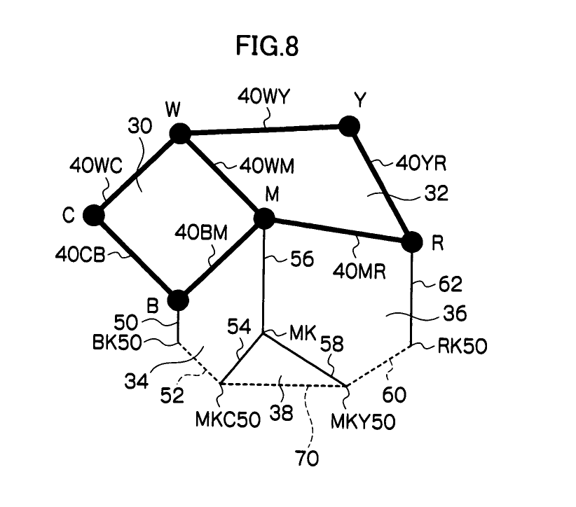

An example of a projected diagram where a portion of a color gamut contour of an output side device, in a case where a limit has been imposed on the amount of color, is projected flatly in FIG. 8.

In the same diagram, a contour surface 30 encircled with a line that connects each apex of the primary and secondary colors of W (white), C (cyan), B (blue) and M (magenta); and a contour surface 32 encircled with a line that connects each apex of the primary and secondary colors of W (white), M (magenta), R (red) and Y (yellow) correspond to a portion of the contour surface of the upper side portion of the color reproducing range shown in FIG. 4. Further, contour surfaces 34, 36, 38 correspond to a portion of the contour surface of the lower side portion of the color reproducing range shown in FIG. 4. The contour surfaces 34, 36 are the contour surfaces formed when black (K) is added to the primary colors (Y, M, C) and the secondary colors (R, G, B). The contour surface 38 is a contour surface formed 100% from black. Note that the contour composition points on each edge line and in each contour surface have been omitted for the sake of simplifying the drawing.

The contour surface 34 is a surface enclosed by lines that connect each apex of the B, M, MK (M: 100%, K: 100%), MKC50 (M: 100%, K: 100%, C: 50%), and BK50 (C: 100%, M: 100%, K: 50%).

The contour surface 36 is a surface enclosed by lines that connect each apex of the M, R, RK (M: 100%, Y: 100%, K: 50%), MKY50 (M: 100%, K: 100%, Y: 50%), and MK (M: 100%, K: 100%).

The contour surface 38 is a surface enclosed by lines that connect each apex of the MK (M: 100%, K: 100%), MKY50 (M: 100%, K: 100%, Y: 50%), and MKC50 (M: 100%, K: 100%, C: 50%).

Note that the edge line 70 connecting MKC50 with MKY50, the edge line 50 connecting BK50 and MKC50, and the edge line 60 connecting RK50 and MKY50 are formed anew. These edge lines occur at the boundary portions of the color gamut contour reduced by the total limit on color material (i.e., at the color gamut contour surface, the boundary portions of the surfaces formed from color gamut contour points that are in accordance with the total limit on color material and the other surfaces). Given that these are edge lines that do not exist in the color gamut contour to which the total limit on color material has not been imposed, these types of edge lines are referred to as pseudo-edge lines.

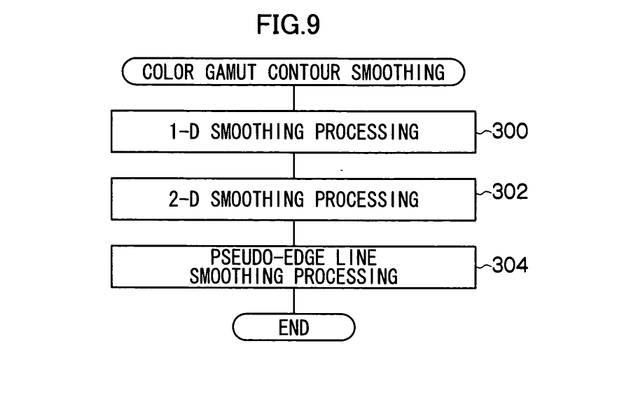

Then, at Step 202, smoothing processing such as shown in FIG. 9 is performed based on the color gamut contour data, and smoothed color gamut contour data is generated. As shown in FIG. 9, one-dimensional smoothing processing is performed at Step 300.

More specifically, contour composition points exist among the contour composition points of the smoothing object the white point (W) on each edge line that connects the Y, M, C, which are the points of primary color 100%, and on each edge line that connects the points of these primary colors 100% with R, G, B that are the points of secondary color 200%. The white color points that are the principal color W and the contour composition points excluding Y, M, C, R, G, B, are made the contour composition points. Namely, the thick lines in FIG. 8 (the edge line 40WC connecting W and C, the edge line 40CB connecting C and B, the edge line 40BM connecting B and M, the edge line 40WM connecting W and M, the edge line 40WY connecting W and Y, the edge line 40YR connecting Y and R, and the edge line 40MR connecting M and R), and these are where the contour composition points exist on. 1-D smoothing processing is performed on the objects of these contour composition points to be smoothed.

For this one-dimensional smoothing processing, a publicly known method can be used, just as in the first exemplary embodiment. For example, a 1-D filter with a length of three and a filter coefficient (β, α, β) is used and smoothing processing is performed one-dimensionally, just as in the first exemplary embodiment, for the contour composition points on the thick lines.

Note that when performing 1-D smoothing processing, it is preferable that smoothing processing using a 1-D filter not be performed across the white points (W) removed from the contour composition points of the objects to be smoothened, and the Y, M, C that are points of 100% primary color and the R, G, B that are points of 200% secondary color (hereafter, these are referred to as “points removed from smoothing”). For this reason, when, for example, a 1-D filter with a length of five or more is used and 1-D smoothing processing is performed, in this case as well, it is better to use a smoothing filter whose length is, e.g., three for the contour composition points on the object to be smoothed that adjoin the points removed from smoothing.

Further, with this exemplary embodiment, the created color gamut is one of a CIELab space so the 1-D smoothing processing is performed for each element of the L*, a*, b*.

Next, at Step 302, 2-D smoothing processing is performed. Specifically, 2-D smoothing processing is performed on all contour composition points except for the points removed from smoothing, the contour composition points that underwent 1-D smoothing processing, and the contour composition points on the pseudo-edge lines. That is, 2-D smoothing processing is performed on the contour composition points in the contour surfaces 30, 32, 34, 36, 38 of FIG. 8; and on the contour composition points that exist on the edge line 50 connecting B and BK50, the edge line 54 connecting MKC50 and MK, the edge line 56 connecting MK and M, the edge line 58 connecting MK and MKY50, and the edge line 62 connecting RK50 and R, all shown in detail in FIG. 8.

This 2-D smoothing processing can be performed with the same method as in the first exemplary embodiment. For example, smoothing processing can be performed on the contour composition points of the objects to be smoothened in the contour surface 30 while moving a 3×3 2-D filter in the direction from C towards W and from C towards B.

There are also other methods by which smoothing of the contour composition points can be performed, such as when focusing on the contour composition points of certain objects to be smoothed, multiple adjoining contour composition points are extracted. A standardized weight is calculated for each of the extracted contour composition point groups so that the closer their distances are to the contour composition points being focused on, the larger they are (i.e., the calculated weight is standardized so that the sum of the weight is one). By calculating the weighted average using this weight, smoothing of the contour composition points being focused on can be performed.

Note that with 2-D smoothing processing as well, processing is performed for each element of L*, a*, b*, just as in 1-D smoothing processing.

Next, at Step 304, smoothing processing for the pseudo-edge lines is performed. The contour composition points corresponding to the color signals of the output side device that is in accordance with the total limit on color material value are considered the surfaces forming the boundaries cut by the total limit on color material, or points on the edge. In the case of FIG. 8, the edge line 70 connecting MKC50 and MKY50, the edge line 52 connecting BK50 and MKC50, and the edge line 60 connecting RK50 and MKY50 become the pseudo-edge lines. Accordingly, here, 2-D smoothing processing is performed on the contour composition points on the pseudo-edge line and the contour composition points of the periphery of the pseudo-edge line using, e.g., a 3×3 filter such as in Step 302. If strong smoothing is applied to these types of contour composition points on the pseudo-edge line and the contour composition points of the periphery of the pseudo-edge line, the generation of gradation jumps and the like can be suppressed. For this reason, the value of the filter coefficient of the periphery (in the case of FIG. 6, α1-α4, α6-α9) of the filter coefficient of the center of the filter (in the case of FIG. 6, α5) is set as in the filter used for regular smoothing processing, e.g., set at value greater than the filter coefficient used in Step 302. Due to this, smoothing processing that is stronger than the 2-D smoothing processing in Step 302 is performed. Note that multiple smoothing processes can be performed on the pseudo-edge lines using the filter used with regular smoothing processing. Due to this, smoothing processing stronger than in a regular process can be performed. Further, the above-described strong smoothing processing can also be applied to only the contour composition points on the pseudo-edge line.

This pseudo-edge line smoothing processing is also performed on each element of the L*, a*, b*, as in 1-D smoothing processing and 2-D smoothing processing.

Then, at Step 204 in FIG. 7, the inputted image signal is converted to an outputted image signal within the color reproducing range of the smoothed output side device with a preset color conversion method, as in Step 104 in FIG. 3.

In this manner, with this exemplary embodiment, the smoothness of the contour surfaces of the color reproducing range of the output side device can be improved with the smoothing processing, and it becomes possible to suppress deterioration of gradation qualities, even if the kind of mapping that depends on the condition of the contour surfaces of the color reproducing range is performed. Further, only smoothing of the contour surfaces of the color reproducing range is performed, a process with a relatively small amount of correction, so the reproducing qualities of the colors mapped on the contours of the color reproducing range of the output side device can be maintained almost entirely as they were, and negative effects on the reproducing qualities within the color reproducing range can be prevented.

Also, with regard to the pseudo-edge lines generated by the reduction of color reproducing range due to the total limit on color material, the smoothness of the color gamut contour surface shapes are important, even if the color reproducing range becomes narrower to a certain extent, so strong smoothing is performed. Due to this, the pseudo-edge lines can be made smooth and the occurrence of gradation jumps and pseudo-outlines can be suppressed.

Note that with each of the above-described exemplary embodiments, the processes are performed so that color conversion is performed after the color reproducing range contours of the output side device are made and smoothened. Nonetheless, creation of the contours and smoothing processing can be performed in advance, so that when converting color, only color conversion processing is performed.

What is claimed is:

1. A color gamut contour creating device comprising:
a color gamut contour creating component that generates color gamut contour data representing a color gamut contour of a color reproducing range in a preset color space of an output side device; and
a color gamut contour smoothing component that generates smoothed color gamut contour data of the color gamut contour where the color gamut contour is smoothed based on the color gamut contour data.

2. The color gamut contour creating device of claim 1, wherein the color gamut contour creating component makes each apex of each polygon, at the time the color gamut contour is divided into a plurality of polygons, into a contour composition points and generates color gamut contour data based on the position of the contour composition points in a color space.

3. The color gamut contour creating device of claim 2, wherein the color gamut contour smoothing component performs 1-D smoothing processing for contour composition points on an edge line that connects a plurality of primary colors in advance from among contour composition points that form the color gamut contour.

4. The color gamut contour creating device of claim 2, wherein the color gamut contour smoothing component performs 2-D smoothing processing for contour composition points with the exception of contour composition points on an edge line that connects a plurality of primary colors in advance from among contour composition points that form the color gamut contour.

5. The color gamut contour creating device of claim 2, wherein after the color gamut contour smoothing component performs 1-D smoothing processing for contour composition points on an edge line that connects a plurality of primary colors in advance from among contour composition points that form the color gamut contour, the color gamut contour smoothing component performs 2-D smoothing processing for contour composition points with the exception of contour composition points on the edge line from among contour composition points that form the color gamut contour.

6. The color gamut contour creating device of claim 2, wherein
the color gamut contour creating component generates color gamut contour data representing a color gamut contour where a color amount of an output device is limited, and
the color gamut contour smoothing component performs smoothing processing for the contour composition points on the pseudo-edge line created due to the amount of color being limited.

7. The color gamut contour creating device of claim 6, wherein the color gamut contour smoothing component performs smoothing processing for contour composition points on the pseudo-edge line that is stronger than the smoothing processing for other contour composition points.

8. The color gamut contour creating device of claim 1, wherein the color gamut contour smoothing component carries out a smoothing processing with the exception of at least a portion of the apexes of the color reproducing range.

9. A color gamut contour creating method comprising:
generating color gamut contour data representing a color gamut contour that is a surface of a color reproducing range in a preset color space of an output side device; and
generating smoothed color gamut contour data of a smoothed color gamut contour where the color gamut contour is smoothed based on the color gamut contour data.

10. A storage medium readable by a computer, the storage medium storing a program of instructions executable by the computer to perform a function for color gamut contour creation, the function comprising:
generating color gamut contour data representing a color gamut contour that is a surface of a color reproducing range in a preset color space of an output side device; and
generating smoothed color gamut contour data of a smoothed color gamut contour where the color gamut contour is smoothed based on the color gamut contour data.

11. A computer data signal embodied in a carrier wave, the computer data signal including a program of instructions executable by the computer to perform a function for color gamut contour creation, the function comprising:
generating color gamut contour data representing a color gamut contour that is a surface of a color reproducing range in a preset color space of an output side device; and
generating smoothed color gamut contour data of a smoothed color gamut contour where the color gamut contour is smoothed based on the color gamut contour data.
